(19) United States
(12) Patent Application Publication
(10) Pub. No.: US 2012/0242630 A1
(43) Pub. Date: Sep. 27, 2012

(54) SHIFT REGISTER

(75) Inventor: Masanori Ohara, Osaka-shi (JP)

(73) Assignee: SHARP KABUSHIKI KAISHA, Osaka-shi, Osaka (JP)

(21) Appl. No.: 13/513,686

(22) PCT Filed: Jul. 21, 2010
(86) PCT No.: PCT/JP2010/062223

§ 371 Date: Jun. 4, 2012

(30) Foreign Application Priority Data
Dec. 28, 2009 (JP) 2009-298547

(51) Int. Cl. G09G 5/00; G11C 19/00

(52) U.S. Cl. 345/204; 377/64

(57) ABSTRACT

Unit circuits 11 each including a TFT T2 (output transistor), a TFT T1 (input transistor), and a TFT T8 (output reset transistor) are cascade-connected, and a gate terminal of the TFT T8 is connected to a gate terminal of the TFT T2 included in a next stage unit circuit 11. By applying a post-boot potential that is higher than an ON potential of the TFT T8 to the gate terminal of the TFT T8, driving capability of the TFT T8 is increased. Accordingly, it is possible to reduce falling time duration of the output signal Q and a layout area of the TFT T8. In this manner, a shift register with a small area capable of resetting an output signal at high speed is provided.

### TECHNICAL FIELD

The present invention relates to shift registers, and in particular to a shift register suitably used in a drive circuit for a display device, and the like.

### BACKGROUND ART

An active matrix-type display device selects two-dimensionally arranged pixel circuits by line, and writes gradation voltages to the selected pixel circuits according to a video signal, thereby displaying an image. Such a display device is provided with a scanning signal line drive circuit including a shift register, in order to select the pixel circuits by line.

Further, as a method of downsizing display devices, there is known a method of monolithically providing a scanning signal line drive circuit on a display panel along with pixel circuits using a manufacturing process of providing TFTs (Thin Film Transistors) within the pixel circuit. A display panel having a scanning signal line drive circuit monolithically provided is also referred to as a gate driver monolithic panel.

As a shift register included in the scanning signal line drive circuit, various circuits have been known conventionally (Patent Documents 1 to 4, for example). Patent Document 1 describes a shift register having a plurality of unit circuits 91 shown in FIG. 16 connected in series. This shift register is monolithically provided on a liquid crystal panel using amorphous silicon TFTs.

### PRIOR ART DOCUMENTS

### Patent Documents

[Patent Document 1] Japanese Laid-Open Patent Publication No. 2006-107692

[Patent Document 2] Japanese Laid-Open Patent Publication No. 2004-78172

[Patent Document 3] Japanese Laid-Open Patent Publication No. H8-87897

[Patent Document 4] International Publication Pamphlet No. WO 92/15992

### SUMMARY OF THE INVENTION

### Problems to be Solved by the Invention

Each stage of a shift register is provided with a transistor for falling an output signal (hereinafter referred to as a transistor for falling). For example, in a unit circuit 91 shown in FIG. 16, a transistor TG3 serves as a transistor for falling. In order to cause a display device provided with a shift register including the unit circuits 91 to operate correctly, it is necessary to make a potential of a scanning signal line fall to a low level within a predetermined time period using the transistor TG3 for falling.

In a large-sized display panel, as the length of the scanning signal line increases and a load capacitance of the display panel also increases, it is required to increase driving capability of the transistor for falling accordingly. However, when monolithically providing a scanning signal line drive circuit on a display panel, a transistor provided on the display panel is limited to a certain size, and it is not possible to unlimitedly increase driving capability of the transistor for falling.

Accordingly, a scanning signal line drive circuit monolithically provided on a display panel (especially, a large-sized display panel) poses a problem that insufficient driving capability of the transistor for falling increases falling time duration of an output signal. If the falling time duration exceeds permissible time duration, the display device writes, after writing a gradation voltage to one pixel circuit, a gradation voltage to be written to the next pixel circuit to the same pixel circuit, and therefore the display device is not able to display a screen correctly. If the driving capability is increased by making the size of the transistor for falling larger in order to prevent this from occurring, a layout area of the transistor for falling increases, and the costs for the display panel increase.

Thus, an object of the present invention is to provide a shift register with a small area capable of resetting an output signal at high speed.

### Means for Solving the Problems

According to a first aspect of the present invention, there is provided a shift register configured such that a plurality of unit circuits are cascade-connected and operating based on a plurality of clock signals, wherein each unit circuit includes: an output transistor having one conducting terminal supplied with one of the clock signals and the other conducting terminal connected to an output node; an input transistor configured to apply an ON potential to a control terminal of the output transistor according to a supplied set signal; and an output reset transistor configured to apply an OFF potential to the output node according to a supplied output reset signal, and a control terminal of the output reset transistor is connected to a control terminal of an output transistor included in a next stage unit circuit.

According to a second aspect of the present invention, in the first aspect of the present invention, each unit circuit further includes a state reset transistor configured to apply an OFF potential to the control terminal of the output transistor according to a supplied state reset signal.

According to a third aspect of the present invention, in the first aspect of the present invention, each unit circuit further includes an output reset auxiliary transistor configured to apply an OFF potential to the output node according to another one of the supplied clock signals.

According to a fourth aspect of the present invention, in the first aspect of the present invention, the set signal is supplied to a control terminal and one conducting terminal of the input transistor.

According to a fifth aspect of the present invention, in the first aspect of the present invention, the set signal is supplied to a control terminal of the input transistor, and the ON potential is fixedly applied to one conducting terminal of the input transistor.

According to a sixth aspect of the present invention, in the first aspect of the present invention, each unit circuit further includes an additional output transistor having a control terminal and one conducting terminal connected in an identical configuration with that of the output transistor, and a control terminal of the input transistor is connected to the other conducting terminal of an additional output transistor included in a previous stage unit circuit.

According to a seventh aspect of the present invention, in the first aspect of the present invention, a control terminal of the input transistor is connected to an output node included in a previous stage unit circuit.

According to an eighth aspect of the present invention, in the first aspect of the present invention, all of the transistors included in the unit circuits are of the same conductivity type.

According to a ninth aspect of the present invention, there is provided a display device including: a plurality of pixel circuits arranged two-dimensionally; and a drive circuit including the shift register according to one of the first to eighth aspects.

### Effects of the Invention

According to the first aspect of the present invention, if the clock signal is inputted when the output transistor is in the ON state, the potential of the control terminal of the output transistor becomes the post-boot potential that is higher than the ON potential (or lower than the ON potential) of the output transistor. Therefore, it is possible to increase the driving capability of the output reset transistor by connecting the control terminal of the output reset transistor to the control terminal of the output transistor included in the next stage unit circuit so as to apply the post-boot potential outputted from the next stage unit circuit to the control terminal of the output reset transistor. Accordingly, it is possible to reduce reset time of the output signal, or to reduce the layout area of the output reset transistor.

According to the second aspect of the present invention, by providing the state reset transistor, the output transistor can be controlled to be in the OFF state.

According to the third aspect of the present invention, by providing the output reset auxiliary transistor, the output signal can be reset without fail according to the other clock signal.

According to the fourth aspect of the present invention, by supplying the set signal to the control terminal and the one conducting terminal of the input transistor, it is possible to apply the ON potential to the control terminal of the output transistor using the input transistor.

According to the fifth aspect of the present invention, by supplying the set signal to the control terminal of the input transistor and applying the ON potential to the one conducting terminal, it is possible to apply the ON potential to the control terminal of the output transistor using the input transistor.

According to the sixth aspect of the present invention, by providing the additional output transistor, and by separately outputting, from the unit circuit, the output signal to the outside and an input signal to the other unit circuit, it is possible to prevent the shift register from erroneously operating.

According to the seventh aspect of the present invention, by connecting the control terminal of the input transistor to the output node included in the previous stage unit circuit, the input transistor can be controlled with a simple circuit configuration.

According to the eighth aspect of the present invention, it is possible to reduce manufacturing cost of the shift register by using the transistors of the same conductivity type.

According to the ninth aspect of the present invention, it is possible to obtain a low-cost display device that can correctly display a screen using a shift register with a reduced area and capable of resetting the output signal at high speed.

### BRIEF DESCRIPTION OF THE DRAWINGS

FIG. 1 is a block diagram showing a configuration of a liquid crystal display device according to embodiments of the present invention.

FIG. 2 is a block diagram showing a configuration of a shift register according to a first embodiment of the present invention.

FIG. 3 is a timing chart of clock signals supplied to the shift register shown in FIG. 2.

FIG. 4 is a circuit diagram of a unit circuit included in the shift register shown in FIG. 2.

FIG. 5 is a timing chart of the shift register shown in FIG. 2.

FIG. 6 is a timing chart of signals outputted from the shift register shown in FIG. 2.

FIG. 7 is a circuit diagram in which a parasitic capacitance is added to FIG. 4.

FIG. 8 is a signal waveform diagram of a signal outputted from the shift register shown in FIG. 2.

FIG. 9 is a block diagram showing a configuration of a shift register according to a second embodiment of the present invention.

FIG. 10 is a timing chart of clock signals supplied to the shift register shown in FIG. 9.

FIG. 11 is a timing chart of signals outputted from the shift register shown in FIG. 9.

FIG. 12 is a circuit diagram of a unit circuit included in a shift register according to a first modified example of the present invention.

FIG. 13 is a circuit diagram of a unit circuit included in a shift register according to a second modified example of the present invention.

FIG. 14 is a circuit diagram of a unit circuit included in a shift register according to a third modified example of the present invention.

FIG. 15 is a circuit diagram of a unit circuit included in a shift register according to a fourth modified example of the present invention.

FIG. 16 is a circuit diagram of a unit circuit included in a conventional shift register.

### MODE FOR CARRYING OUT THE INVENTION

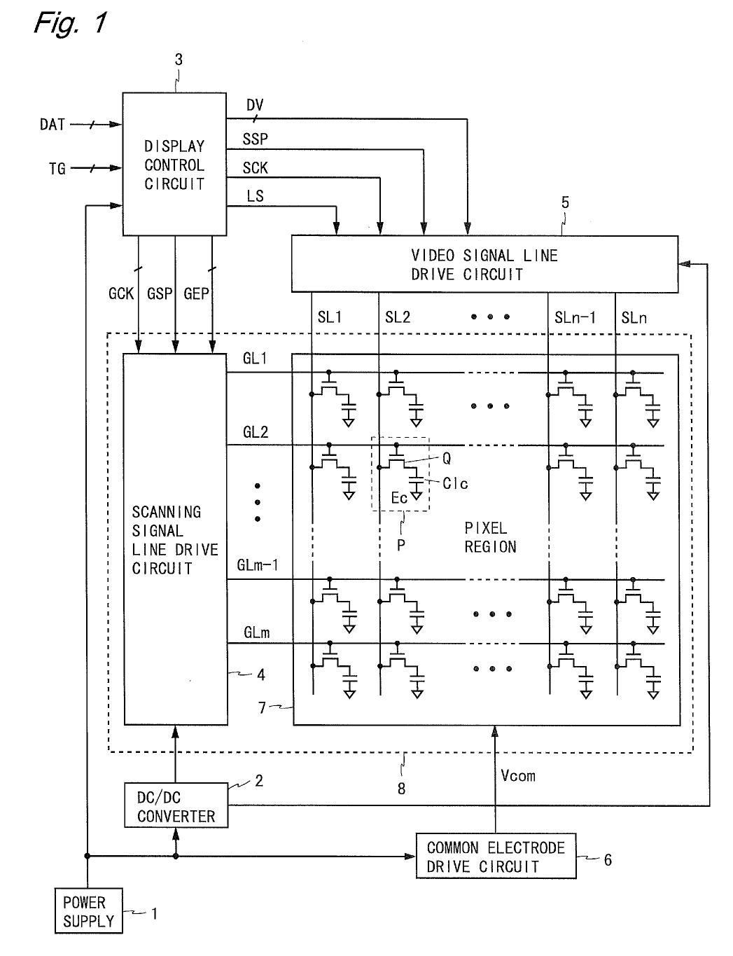

FIG. 1 is a block diagram showing a configuration of a liquid crystal display device according to embodiments of the present invention. The liquid crystal display device shown in FIG. 1 is an active matrix-type display device provided with a power supply 1, a DC/DC converter 2, a display control circuit 3, a scanning signal line drive circuit 4, a video signal line drive circuit 5, a common electrode drive circuit 6, and a pixel region 7. The scanning signal line drive circuit 4 and the video signal line drive circuit 5 are also referred to as a gate driver circuit and a source driver circuit, respectively. In the following description, m and n are assumed to be integers not smaller than 2.

The pixel region 7 includes m scanning signal lines GL1 to GLm, n video signal lines SL1 to SLn, and (m×n) pixel circuits P. The scanning signal lines GL1 to GLm are arranged in parallel with each other, and the video signal lines SL1 to SLn are arranged in parallel with each other so as to orthogonally intersect with the scanning signal lines GL1 to GLm. The (m×n) pixel circuits P are arranged two-dimensionally so as to respectively correspond to intersections between the scanning signal lines GL1 to GLm and the video signal lines SL1 to SLn.

Each pixel circuit P includes a TFT Q and a liquid crystal capacitor Clc. A gate terminal of the TFT Q is connected to a corresponding one of the scanning signal lines, a source terminal of the TFT Q is connected to a corresponding one of the video signal lines, and a drain terminal of the TFT Q is connected to one electrode of the liquid crystal capacitor Clc. The other electrode of liquid crystal capacitor Clc is a counter electrode Ec that faces all of the pixel circuits P. Each pixel circuit P serves as a single pixel (or a single sub-pixel). It should be noted that each pixel circuit P can also include an auxiliary capacitor in parallel with the liquid crystal capacitor Clc.

The power supply 1 supplies a predetermined power supply voltage to the DC/DC converter 2, the display control circuit 3, and the common electrode drive circuit 6. The DC/DC converter 2 generates a predetermined direct voltage based on the power supply voltage supplied from the power supply 1, and supplies the generated voltage to the scanning signal line drive circuit 4 and the video signal line drive circuit 5. The common electrode drive circuit 6 applies a predetermined potential Vcom to a common electrode Ec.

The display control circuit 3 outputs a digital video signal DV and a plurality of control signals based on an image signal DAT and a group of timing signals TG that are supplied from the outside. The group of timing signals TG includes a horizontal synchronizing signal, a vertical synchronizing signal and the like. The control signals outputted from the display control circuit 3 include a source start pulse signal SSP, a source clock signal SCK, a latch strobe signal LS, a gate clock signal GCK, a gate start pulse signal GSP, and a gate end pulse signal GEP. The gate clock signal GCK includes four signals, the gate start pulse signal GSP includes one or two signals, and the gate end pulse signal GEP includes two or four signals (details will be described later).

The scanning signal line drive circuit 4 selects one of the scanning signal lines GL1 to GLm sequentially based on the gate clock signal GCK, the gate start pulse signal GSP, and the gate end pulse signal GEP outputted from the display control circuit 3, and applies a potential for turning the TFT Q to an ON state (high level potential) to the selected scanning signal line. Accordingly, n pixel circuits P connected to the selected scanning signal line are selected collectively.

The video signal line drive circuit 5 applies n gradation voltages respectively to the video signal lines SL1 to SLn according to the digital video signal DV, based on the digital video signal DV, the source start pulse signal SSP, the source clock signal SCK, and the latch strobe signal LS outputted from the display control circuit 3. Accordingly, the n gradation voltages are written respectively to the n pixel circuits P selected using the scanning signal line drive circuit 4. By writing gradation voltages to all of the pixel circuits P within the pixel region 7 using the scanning signal line drive circuit 4 and the video signal line drive circuit 5, it is possible to display an image based on the image signal DAT in the pixel region 7.

The scanning signal line drive circuit 4 is monolithically provided on a liquid crystal panel 8 having the pixel region 7 provided thereon. TFTs included in the scanning signal line drive circuit 4 are formed using amorphous silicon, microcrystalline silicon, or oxide semiconductor, for example. It should be noted that all or a part of other circuits included in the liquid crystal display device can be monolithically provided on the liquid crystal panel 8.

The scanning signal line drive circuit 4 includes a shift register configured such that a plurality of unit circuits are cascade-connected and that operates based on a plurality of clock signals. The liquid crystal display device according to the embodiments of the present invention has a characteristic in a circuit configuration of the shift register included in the scanning signal line drive circuit 4. Hereinafter, the shift register included in the scanning signal line drive circuit 4 will be described.

### First Embodiment

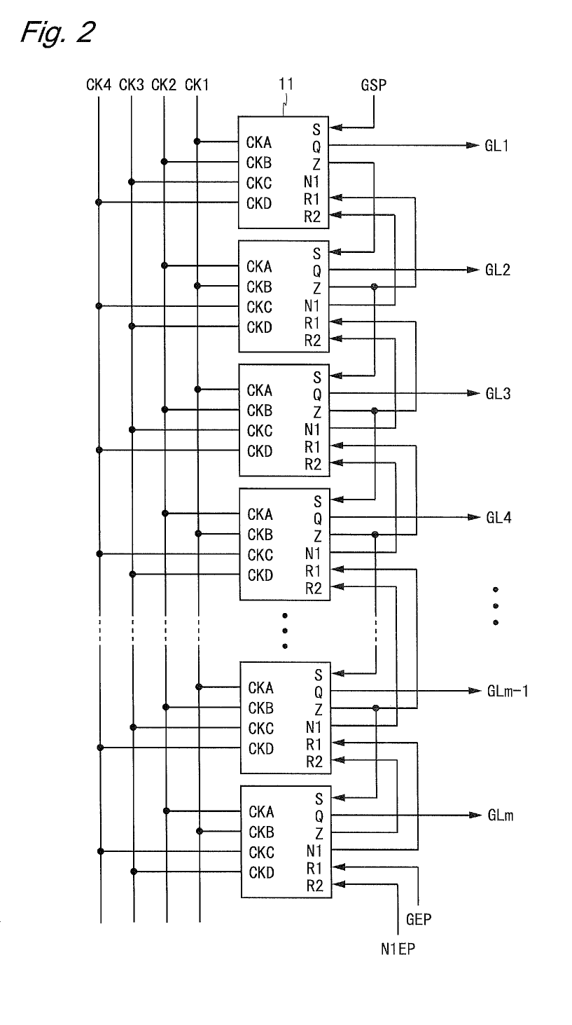

FIG. 2 is a block diagram showing a configuration of a shift register according to a first embodiment of the present invention. The shift register shown in FIG. 2 includes m unit circuits 11 arranged one-dimensionally. In the following description, a unit circuit 11 in an i-th position (i is an integer not smaller than 1 and not greater than m) is referred to as an i-th unit circuit UC (i). In this embodiment, m is assumed to be a multiple of 2.

The shift register shown in FIG. 2 is supplied with four clock signals CK1 to CK4 as the gate clock signal GCK, a single signal as the gate start pulse signal GSP, and a first gate end pulse signal GEP and a second gate end pulse signal N1EP as the gate end pulse signal GEP.

Each unit circuit 11 is supplied with the four clock signals CKA, CKB, CKC, and CKD, a set signal S, a state reset signal R1, an output reset signal R2, and a low level potential VSS (not shown). Each unit circuit 11 outputs an output signal Q, an additional output signal Z, and a state signal N1. The additional output signal Z changes in the same manner as the output signal Q.

When k is assumed to be an integer not smaller than 1 and not greater than (m/2), the clock signals CK1, CK2, CK3, and CK4 are inputted to an odd-numbered unit circuit UC (2 k−1) as the clock signals CKA, CKB, CKC, and CKD, respectively. The clock signals CK2, CK1, CK4, and CK3 are inputted to an even-numbered unit circuit UC (2 k) as the clock signals CKA, CKB, CKC, and CKD, respectively.

To a first unit circuit UC (1), the gate start pulse signal GSP is inputted as the set signal S. To the unit circuit UC (i) that is not the first unit circuit, the additional output signal Z outputted from a previous unit circuit UC (i−1) is inputted as the set signal S. To an m-th unit circuit UC (m), the first gate end pulse signal GEP is inputted as the state reset signal R1, and the second gate end pulse signal N1EP is inputted as the output reset signal R2. To the unit circuit UC (i) that is not the m-th unit circuit, the additional output signal Z outputted from a next unit circuit UC (i+1) is inputted as the state reset signal R1, and the state signal N1 outputted from the next unit circuit UC (i+1) is inputted as the output reset signal R2. An i-th scanning signal line GLi is driven based on the output signal Q outputted from the i-th unit circuit UC (i).

As described above, in the shift register shown in FIG. 2, the unit circuit of each stage is supplied with the additional output signal Z outputted from the previous stage unit circuit as the set signal S, the additional output signal Z outputted from the next stage unit circuit as the state reset signal R1, and the state signal N1 outputted from the next stage unit circuit as the output reset signal R2.

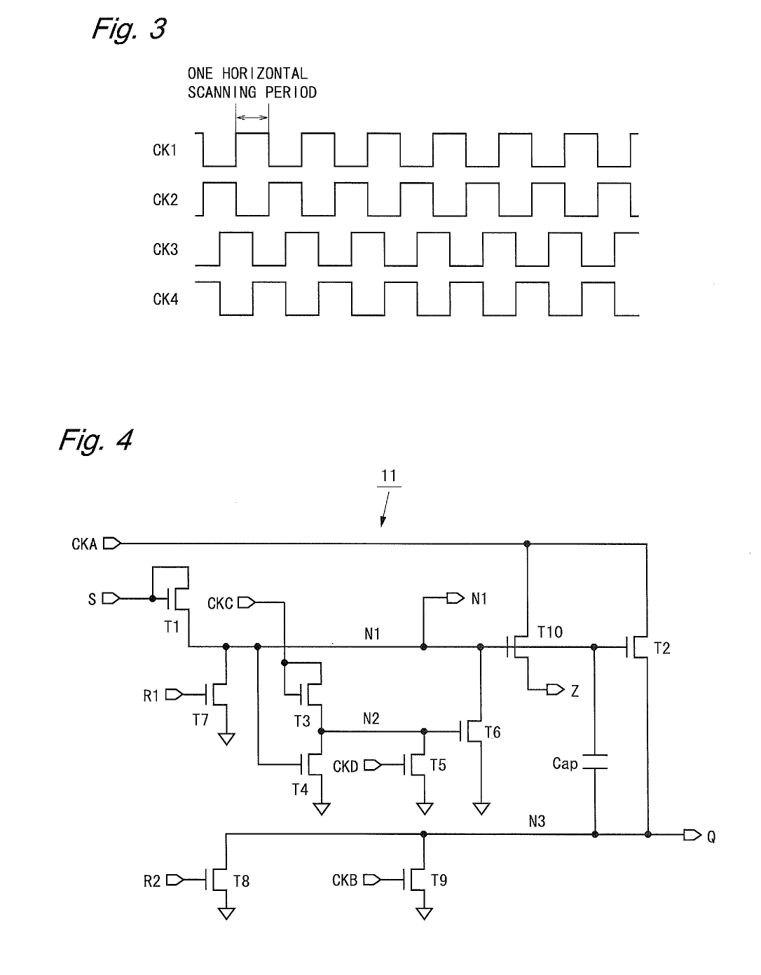

FIG. 3 is a timing chart of the clock signals CK1 to CK4. As shown in FIG. 3, each of the clock signals CK1 to CK4 becomes a high level every other one horizontal scanning period. Phases of the clock signals CK1 and CK2 are displaced from each other by 180 degrees (corresponding to one horizontal scanning period), and phases of the clock signals CK3 and CK4 are also displaced from each other by 180 degrees. The phase of the clock signal CK3 is ahead of the phase of the clock signal CK1 by 90 degrees. The phase of the clock signal CK4 is ahead of the phase of the clock signal CK2 by 90 degrees.

FIG. 4 is a circuit diagram of the unit circuit 11. As shown in FIG. 4, the unit circuit 11 includes ten N-channel type TFTs T1 to T10, and a capacitor Cap. For the N-channel type TFTs, a high level potential is an ON potential and a low level potential is an OFF potential. A source terminal of the TFT T1, drain terminals of the TFTs T6 and T7, gate terminals of the TFTs T2, T4, and T10, and one end of the capacitor Cap are connected to a node N1. A source terminal of the TFT T3, drain terminals of the TFTs T4 and T5, and a gate terminal of the TFT T6 are connected to a node N2. A source terminal of the TFT T2, drain terminals of the TFTs T8 and T9, and the other end of the capacitor Cap are connected to an output node N3.

To a gate terminal and a drain terminal of the TFT T1, the set signal S is supplied. To drain terminals of the TFTs T2 and T10, the clock signal CKA is supplied. To a gate terminal and a drain terminal of the TFT T3, the clock signal CKC is supplied. To gate terminals of the TFTs T5, T7, T8, and T9, the clock signal CKD, the state reset signal R1, the output reset signal R2, and the clock signal CKB are supplied, respectively. To source terminals of the TFTs T4 to T9, the low level potential VSS is fixedly applied.

The output node N3 is connected to an output terminal, and the output signal Q is outputted from this output terminal. A source terminal of the TFT T10 is connected to another output terminal, and the additional output signal Z is outputted from this output terminal. The node N1 is connected to further another output terminal, and the state signal N1 is outputted from this output terminal.

The TFT T1 keeps the potential of the node N1 at a high level while the set signal S is at a high level. The set signal S is the additional output signal Z outputted from the previous stage unit circuit 11. Therefore, when an output from the previous stage unit circuit 11 becomes a high level, the potential of the node N1 rises up to a high level. The TFT T2 outputs the clock signal CKA as the output signal Q while the potential of the node N1 is at a high level.

The TFT T3 keeps the potential of the node N2 at a high level while the clock signal CKC is at a high level. The TFT T4 keeps the potential of the node N2 at a low level while the potential of the node N1 is at a high level. If the potential of the node N2 becomes a high level erroneously during a selection period of a corresponding one of the scanning signal lines, the TFT T6 is turned to an ON state, the potential of the node N1 falls, and the TFT T2 is turned to an OFF state. The TFT T4 is provided in order to prevent such a phenomenon from occurring.

The TFT T5 keeps the potential of the node N2 at a low level while the clock signal CKD is at a high level. In a case in which the TFT T5 is not provided, the potential of the node N2 is always at a high level other than the selection period of the corresponding one of the scanning signal lines, and bias voltages are kept being applied to the TFTs T6 and T10. If this situation continues, threshold voltages of the TFTs T6 and T10 rise, and neither the TFTs T6 nor T10 functions correctly as a switch. The TFT T5 is provided in order to prevent such a phenomenon from occurring.

The TFT T6 keeps the potential of the node N1 at a low level while the potential of the node N2 is at a high level. The TFT T7 keeps the potential of the node N1 at a low level while the state reset signal R1 is at a high level. The state reset signal R1 is the additional output signal Z outputted from the next stage unit circuit 11. Therefore, when an output from the next stage unit circuit 11 becomes a high level, the potential of the node N1 falls down to a low level.

The TFT T8 applies a low level potential to the output node N3 while the output reset signal R2 is at a high level. The output reset signal R2 is the state signal N1 outputted from the next stage unit circuit 11. The TFT T8 has a function of falling the output signal Q according to the potential of the node N1 included in the next stage unit circuit 11.

The TFT T9 applies a low level potential to the output node N3 while the clock signal CKB is at a high level. The TFT T10 outputs the clock signal CKA as the additional output signal Z while the potential of the node N1 is at a high level. The capacitor Cap is a compensation capacitor for maintaining the potential of the node N1 at a high level. The capacitor Cap is provided in order to prevent the potential of the node N1 from falling.

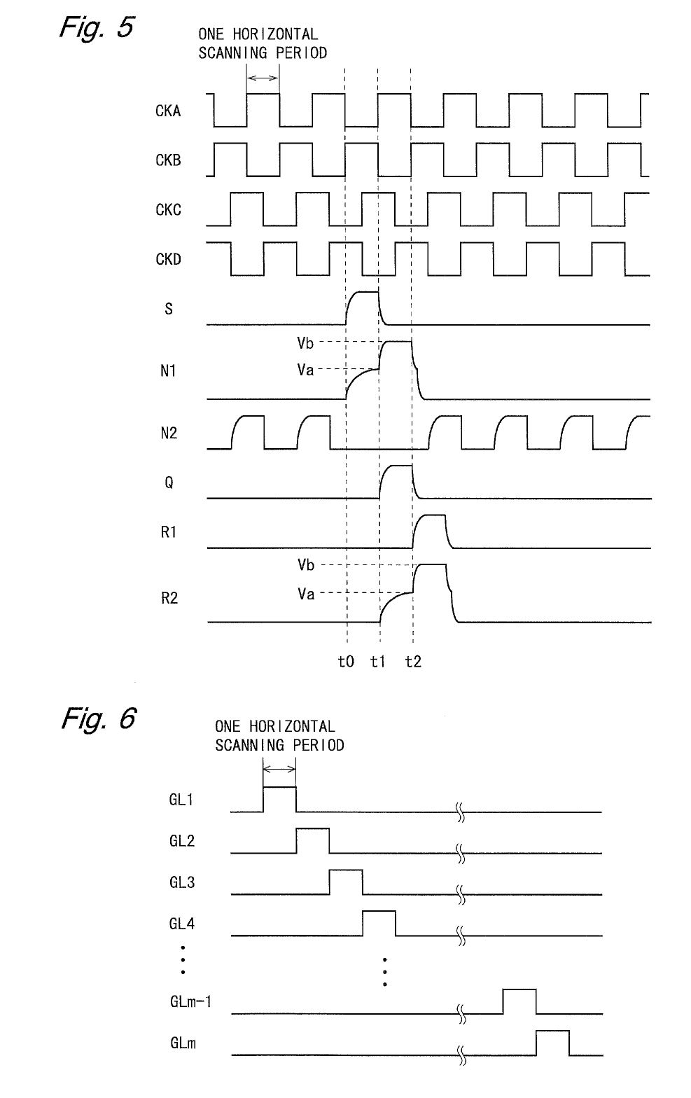

FIG. 5 is a timing chart of the shift register according to this embodiment. The clock signals CKA, CKB, CKC, and CKD inputted to the unit circuit 11 change as shown in FIG. 5. At time t0, the set signal S (an output from a previous stage unit circuit) changes from a low level to a high level. As the TFT T1 is diode-connected, when the set signal becomes a high level, the potential of the node N1 becomes a high level (hereinafter, the potential of the node N1 at this time is referred to as a pre-boot potential Va). Accordingly, the TFT T2 is turned to the ON state. Further, as the TFT T4 is also turned to the ON state, the potential of the node N2 becomes a low level, and the TFT T6 is turned to the OFF state.

At time t1, the clock signal CKA changes from a low level to a high level. To the drain terminal of the TFT T2, the clock signal CKA is supplied, and the capacitor Cap is present between the gate and the source of the TFT T2. Further, the TFT T2 is in the ON state at this time, and no potential is applied to the node N1 from the outside. Accordingly, when a potential at the drain terminal of the TFT T2 rises, the potential of the node N1 also rises (bootstrap effect). Therefore, the TFT T2 is in a state in which a potential higher than the pre-boot potential Va is applied to the gate terminal (hereinafter, the potential of the node N1 at this time is referred to as a post-boot potential Vb). The post-boot potential Vb is higher than the high level potential of the clock signal CKA. As the clock signal CKA becomes a high level in a time period from the time t1 to time t2, the potential of the node N1 reaches the post-boot potential Vb substantially in the same time period.

After a short time after the time t1, the output reset signal R2 (the potential of the node N1 of the next stage unit circuit) changes from a low level to a high level (the potential of the output reset signal R2 becomes the pre-boot potential Va). Accordingly, the TFT T8 is turned to the ON state. The unit circuit 11 is configured such that, when the post-boot potential Vb is applied to the gate terminal of the TFT T2 and the pre-boot potential Va is applied to the gate terminal of the TFT T8, a current flowing through the TFT T2 is larger than a current flowing through the TFT T8. Therefore, after the time t1, a potential of the output node N3 rises, and the output signal Q becomes a high level. At this time, the scanning signal line to which the output signal Q is applied is in the selected state, and writing of the gradation voltage is performed to the plurality of pixel circuits P connected to this scanning signal line.

At the time t2, the clock signal CKA changes from a high level to a low level, and the clock signal CKB and the state reset signal R1 (an output from the next stage unit circuit) change from a low level to a high level. At this time, the TFTs T7 and T9 are tuned to the ON state. When the TFT T7 is tuned to the ON state, the potential of the node N1 changes to a low level, and the TFT T2 is tuned to the OFF state. By contrast, the TFT T8 remains in the ON state after the time t2. Therefore, by the action of the TFT T8, the potential of the output node N3 falls, and the output signal Q becomes a low level.

After a short time after the time t2, the potential of the output reset signal R2 further rises from the pre-boot potential Va to the post-boot potential Vb. When the post-boot potential Vb is applied to the gate terminal, driving capability of the TFT T8 increases. Therefore, by the action of the TFT T8 whose gate terminal is applied with the post-boot potential Vb, the output signal Q changes to a low level at high speed. Further, by the action of the TFT T9 that is turned to the ON state at the time t2, the change of the output signal Q to a low level is promoted.

The clock signals of four phases shown in FIG. 3 are supplied to the shift register shown in FIG. 2, and the gate start pulse signal GSP, the first gate end pulse signal GEP, and the second gate end pulse signal N1EP are controlled to be a high level for one horizontal scanning period at predetermined timing. Accordingly, a pulse inputted to a unit circuit of a first stage (first unit circuit UC (1)) is sequentially transferred to a unit circuit of a last stage (m-th unit circuit UC (m)). At this time, the potentials of the scanning signal lines GL1 to GLm are changed to a high level sequentially for one horizontal scanning period (see FIG. 6).

Here, a shift register configured such that the plurality of unit circuits 11 are cascade-connected and the gate terminal of the TFT T8 is connected to the source terminal of the TFT T10 included in the next stage unit circuit 11 is considered as a conventional shift register. When the TFT T10 is in the ON state, as a potential of the source terminal of the TFT T10 is substantially equal to the potential of the clock signal CKA, a potential at the gate terminal of the TFT T8 rises only up to the high level potential of the clock signal. Accordingly, the conventional shift register has a problem that insufficient driving capability of the TFT T8 increases falling time duration of the output signal Q (time required before the signal becomes a low level).

By contrast, in the shift register according to this embodiment, the gate terminal of the TFT T8 is connected to the gate terminal of the TFT T2 included in the next stage unit circuit 11. The potential at the gate terminal of the TFT T8 (the potential of the node N1) rises up to the post-boot potential Vb that is higher than the high level potential of the clock signal. Therefore, according to the shift register of this embodiment, by applying the post-boot potential Vb outputted from the next stage unit circuit 11 to the gate terminal of the TFT T8, it is possible to improve the driving capability of the TFT T8 and to decrease the falling time duration of the output signal Q. Alternatively, it is possible to reduce a layout area of the TFT T8 by reducing a channel width of the TFT T8.

The following describes an effect of decreasing the falling time duration of the output signal Q. When the TFT T8 operates in a linear region, a current I8 flowing through the TFT T8 is given by an expression (1) shown below.

I8=(W8/L)μCox{(Vg8−Vt)Vd8−(1/2)Vd8²} (1)

Here, W8 is a gate width of the TFT T8, Vg8 is a voltage applied to the gate of the TFT T8, Vd8 is a voltage applied to the drain of the TFT T8, μ is a carrier mobility, Vt is a threshold voltage of the TFTs, L is a gate length of the TFTs, and Cox is a gate oxide capacitance of the TFTs. Values of μ, Vt, L, and Cox are common to all the TFTs included in the shift register.

When the output signal Q is falling, the post-boot potential Vb is applied to the gate terminal of the TFT T8. The post-boot potential Vb is given approximately by an expression (2) shown below.

Vb=(VCK−Vt)+(Cap10/Ctot)VCK+(Cap2/Ctot)VCK (2)

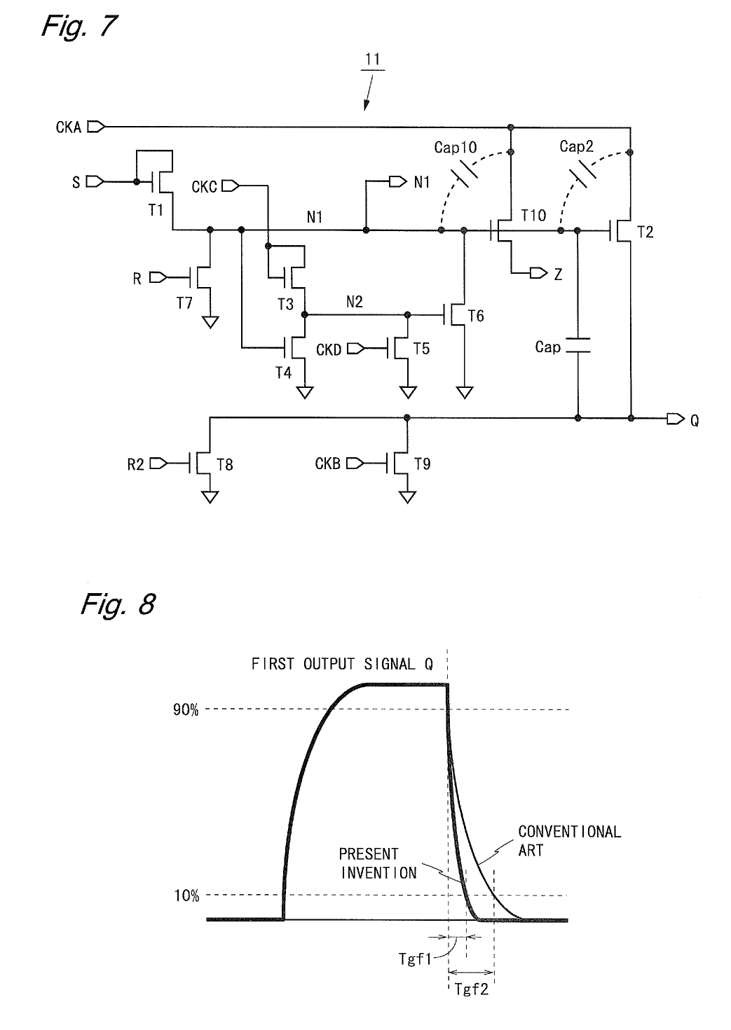

Here, VCK is a high level potential of the clock signal, Cap10 is a capacitance value of a parasitic capacitance between the gate and the drain of the TFT T10 (see FIG. 7), Cap2 is a capacitance value of a parasitic capacitance between the gate and the drain of the TFT T2, Ctot is a total of capacitance values of all parasitic capacitances accompanied with the node N1, and (VCK−Vt) is the pre-boot potential Va. The pre-boot potential Va is calculated by subtracting the threshold voltage Vt of the TFT T1 from the high level potential VCK of the clock signal.

As shown in the expression (2), the post-boot potential Vb is determined based substantially on the capacitance values Cap10 and Cap2 as well as on the high level potential VCK of the clock signal. For the shift register according to this embodiment, it is preferable that the capacitance values Cap10 and Cap2 be determined such that the post-boot potential Vb is not smaller than 1.5 times and smaller than 2.0 times of the high level potential VCK of the clock signal.

A case is considered in which, for example, μ=0.3, Cox=2×10⁻⁸, Vb=55,Vd8=VCK=30, Vt=2, L=5, and W8=5000 (where, a unit of the values is arbitrary unit (a.u.), the same applies hereinafter). In the case of the shift register according to this embodiment, Vg8=Vb (=55) when the output signal Q is falling, and therefore the current I8 flowing through the TFT T8 is I8=6.84×10⁻³ according to the expression (1). By contrast, in the case of the conventional shift register, Vg8=VCK (=30) when the output signal Q is falling, and the current flowing through the TFT T8 is I8conv=2.34×10 ⁻³ according to the expression (1).

In this case, the current I8 flowing through the TFT T8 when the output signal Q is falling in the case of the shift register according to this embodiment is about three times larger than that in the conventional example. Accordingly, an amount of electric charge drawn from the scanning signal line per unit time is about three times larger than that in the conventional example, and the falling time duration of the output signal Q is about ⅓ as compared to the conventional example. As described above, according to the shift register of this embodiment, by applying the post-boot potential Vb outputted from the next stage unit circuit 11 to the gate terminal of the TFT T8, it is possible to reduce the falling time duration of the output signal Q by about (I8conv/I8) times (where, I8conv<I8) as compared to the conventional example.

FIG. 8 is a signal waveform diagram of the output signal Q. In FIG. 8, Tgf1 represents a 90% to 10% falling time duration of the output signal Q in the shift register according to this embodiment, and Tgf2 represents the same falling time duration in the conventional shift register. The falling time duration Tgf1 according to this embodiment is about (I8conv/I8) times of the falling time duration Tgf2 in the conventional example.

Next, an effect of reducing the layout area of the TFT T8 is described. If it is not necessary to decrease the falling time duration of the output signal Q (if the conventional falling time duration is acceptable), it is possible to decrease the gate width of the TFT T8 by an amount corresponding to that the driving capability of the TFT T8 is increased by applying the post-boot potential Vb to the gate terminal of the TFT T8, thereby reducing the layout area of the TFT T8.

An example is considered, in which the gate width W8 of the TFT T8 is 5000 in the conventional shift register, and the current I8 flowing through the TFT T8 when the output signal Q is falling is such that I8conv=2.34×10⁻³ for the conventional shift register, and I8=6.84×10⁻³ for the shift register according to this embodiment. In this case, if the falling time duration of the output signal Q of the conventional shift register is acceptable, it is possible to decrease the gate width W8 of the TFT T8 for the shift register according to this embodiment down to 1710 (=5000×2.34/6.84) and to reduce the layout area of the TFT T8 down to about 34% of the conventional example.

According to the shift register according to this embodiment, when both of the TFTs T2 and T8 are in the ON state, the potential of the output node N3 rises due to a difference between the current flowing through the TFT T2 and the current flowing through the TFT T8, and the output signal Q becomes a high level. When the TFT T2 operates in a linear region, a current I8 flowing through the TFT T2 is given by an expression (3) shown below.

I2=(W2/L)μCox{(Vg2−Vt)Vd2−(1/2)Vd2²} (3)

Here, W2 is a gate width of the TFT T2, Vg2 is a voltage applied to the gate of the TFT T2, and Vd2 is a voltage applied to the drain of the TFT T2.

When both of the TFTs T2 and T8 are in the ON state, both Vd2=Vd8˜VCK and Vg2>Vd2hold. The voltage Vg2 is not smaller than 1.5 times and smaller than 2.0 times of the voltage Vd2, for example. Accordingly, if the gate width W2 of the TFT T2 is the same as the gate width W8 of the TFT T8, the current I2 flowing through the TFT T2 becomes sufficiently larger than the current I8 flowing through the TFT T8. Therefore, the output signal Q changes to a high level without fail when both of the TFTs T2 and T8 are in the ON state, and thereafter remains at a high level in a stable manner.

It is assumed that W2=5000 (=W8) in the above example of values, for example. As Vg2=Vb (=55) and Vd2=VCK (=30) for the TFT T2, the current I2 flowing through the TFT T2 is I2=6.84×10⁻³ according to the expression (3). By contrast, as Vg2=Va (=30−2) and Vd2=VCK (=30) for the TFT T8, the current I8 flowing through the TFT T8 is I8=1.98×10⁻³ according to the expression (1). Also in this case, the current I2 flowing through the TFT T2 becomes sufficiently larger than the current I8 flowing through the TFT T8. Therefore, the output signal Q changes to a high level without fail due to the difference between the current flowing through the TFT T2 and the current flowing through the TFT T8.

As described above, the shift register according to this embodiment is configured such that the plurality of the unit circuits 11 are cascade-connected and the shift register operates based on the plurality of clock signals CK1 to CK4. Each unit circuit 11 includes an output transistor (TFT T2) having one conducting terminal (drain terminal) supplied with one of the clock signals (the clock signal CK1 or CK2) and the other conducting terminal (source terminal) connected to the output node N3, an input transistor (TFT T1) that applies an ON potential (high level potential) to a control terminal of the output transistor according to the supplied set signal S, and an output reset transistor (TFT T8) that applies an OFF potential (low level potential) to the output node N3 according to the supplied output reset signal R2. A control terminal of the output reset transistor (the gate terminal of the TFT T8) is connected to the control terminal of the output transistor (the gate terminal of the TFT T2) included in the next stage unit circuit 11.

Accordingly, if the clock signal is inputted when the output transistor is in the ON state, the potential of the control terminal of the output transistor (the potential of the node N1) becomes the post-boot potential Vb that is higher than the ON potential of the output transistor. Therefore, it is possible to increase the driving capability of the output reset transistor by connecting the control terminal of the output reset transistor to the control terminal of the output transistor included in the next stage unit circuit 11 so as to apply the post-boot potential Vb outputted from the next stage unit circuit 11 to the control terminal of the output reset transistor. Accordingly, it is possible to reduce reset time (falling time duration) of the output signal Q, or to reduce the layout area of the output reset transistor.

Each unit circuit 11 further includes a state reset transistor (TFT T7) that applies an OFF potential to the control terminal of the output transistor according to the supplied state reset signal R1. By providing such a state reset transistor, the output transistor can be controlled to be in the OFF state. Moreover, each unit circuit 11 further includes an output reset auxiliary transistor (TFT T9) that applies an OFF potential to the output node N3 according to another one of the supplied clock signals (the clock signal CK1 or CK2). By providing such an output reset auxiliary transistor, the output signal Q can be reset (set to a low level) without fail according to the other clock signal.

Furthermore, the set signal S is supplied to the control terminal and the one conducting terminal of the input transistor (the gate terminal and the drain terminal of the TFT T1). Accordingly, it is possible to apply an ON potential to the control terminal of the output transistor using the input transistor. The unit circuit 11 further includes an additional output transistor (TFT T10) having a control terminal and one conducting terminal (the gate terminal and the drain terminal) connected in the same manner as those of the output transistor. The control terminal of the input transistor (the gate terminal of the TFT T1) is connected to the other conducting terminal of the additional output transistor (the source terminal of the TFT T10) included in the previous stage unit circuit 11. By providing such an additional output transistor, and by separately outputting, from the unit circuit 11, an output signal to the outside and an input signal to the other unit circuit 11, it is possible to prevent the shift register from erroneously operating.

Moreover, all the transistors included in the unit circuit 11 are of the same conductivity type (N-channel type). It is possible to reduce manufacturing cost of the shift register by using the transistors of the same conductivity type. Further, according to the liquid crystal display device provided with the scanning signal line drive circuit 4 including the shift register according to this embodiment, it is possible to obtain a low-cost liquid crystal display device that can correctly display a screen using a shift register with a reduced area and capable of resetting the output signal at high speed.

### Second Embodiment

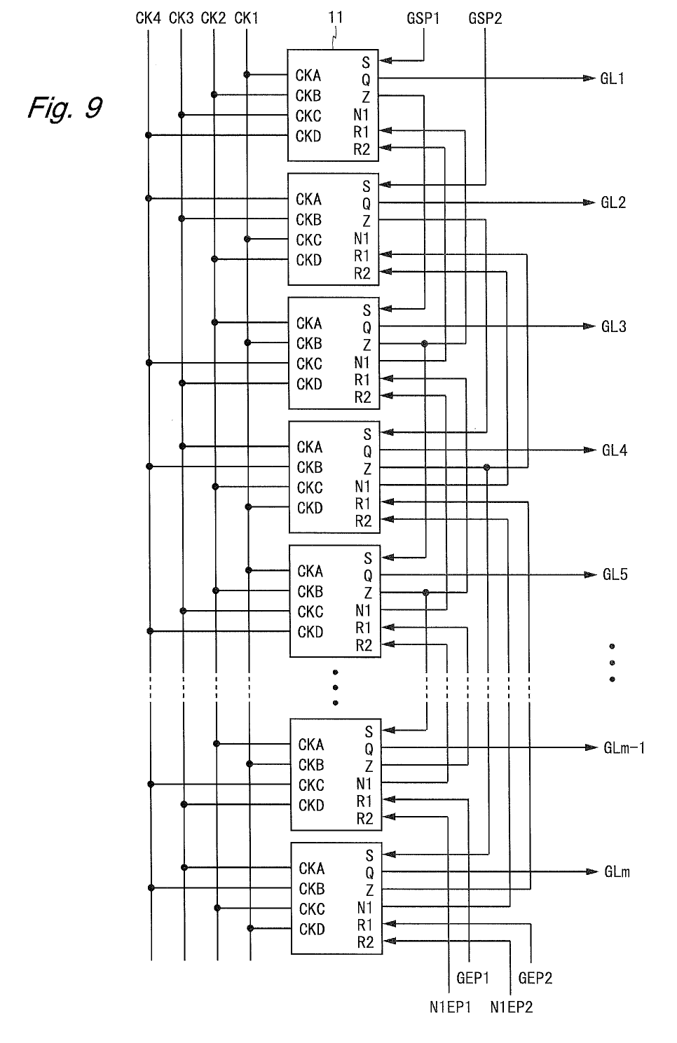

FIG. 9 is a block diagram showing a configuration of a shift register according to a second embodiment of the present invention. FIG. 9 shows m unit circuits 11 arranged one-dimensionally. A first shift register is configured by cascade-connecting odd-numbered ones of the m unit circuits 11. Similarly, a second shift register is configured by cascade-connecting even-numbered ones of the m unit circuits 11. In the following, differences between this embodiment and the first embodiment will be described, and the features provided in common with the first embodiment will not be described. In this embodiment, m is assumed to be a multiple of 4.

The two shift registers shown in FIG. 9 are supplied with the four clock signals CK1 to CK4 as the gate clock signal GCK, a first gate start pulse signal GSP1 and the second gate start pulse signal GSP2 as the gate start pulse signal GSP, and a first gate end pulse signal GEP1, a second gate end pulse signal GSP2, a third gate end pulse signal N1EP1, and a fourth gate end pulse signal N1EP2 as the gate end pulse signal GEP.

When k is assumed to be an integer not smaller than 1 and not greater than (m/4), the clock signals CK1, CK2, CK3, and CK4 are inputted to a (4k−3)-th unit circuit UC (4k−3) as the clock signals CKA, CKB, CKC, and CKD, respectively. The clock signals CK4, CK3, CK1, and CK2 are inputted to a (4 k−2)-th unit circuit UC (4k−2) as the clock signals CKA, CKB, CKC, and CKD, respectively. The clock signals CK2, CK1, CK4, and CK3 are inputted to a (4k−1)-th unit circuit UC (4k−1) as the clock signals CKA, CKB, CKC, and CKD, respectively. The clock signals CK3, CK4, CK2, and CK1 are inputted to a 4k-th unit circuit UC (4k) as the clock signals CKA, CKB, CKC, and CKD, respectively.

To the first unit circuit UC (1), the first gate start pulse signal GSP1 is inputted as the set signal S. To a second unit circuit UC (2), the second gate start pulse signal GSP2 is inputted as the set signal S. To the unit circuit UC (i) that is neither the first unit circuit nor the second unit circuit, the additional output signal Z outputted from a second-previous unit circuit UC (i−2) is inputted as the set signal S. To a (m−1)-th unit circuit UC (m−1), the first gate end pulse signal GEP1 is inputted as the state reset signal R1, and the third gate end pulse signal N1EP1 is inputted as the output reset signal R2. To the m-th unit circuit UC (m), the second gate end pulse signal GSP2 is inputted as the state reset signal R1, and the fourth gate end pulse signal N1EP2 is inputted as the output reset signal R2. To a unit circuit UC (i) that is neither the (m−1)-th unit circuit nor the m-th unit circuit, the additional output signal Z outputted from a second-next unit circuit UC (i+2) is inputted as the state reset signal R1, and the state signal N1 outputted from the second-next unit circuit UC (i+2) is inputted as the output reset signal R2. The i-th scanning signal line GLi is driven based on the output signal Q outputted from the i-th unit circuit UC (i).

In the first shift register configured by the odd-numbered unit circuits 11, the second-previous unit circuit corresponds to the previous stage unit circuit, and the second-next unit circuit corresponds to the next stage unit circuit. This also applies to the second shift register configured by the even-numbered unit circuits 11. As described above, in each of the two shift registers shown in FIG. 9, the unit circuit of each stage is supplied with the additional output signal Z outputted from the previous stage unit circuit as the set signal S, the additional output signal Z outputted from the next stage unit circuit as the state reset signal R1, and the state signal N1 outputted from the next stage unit circuit as the output reset signal R2.

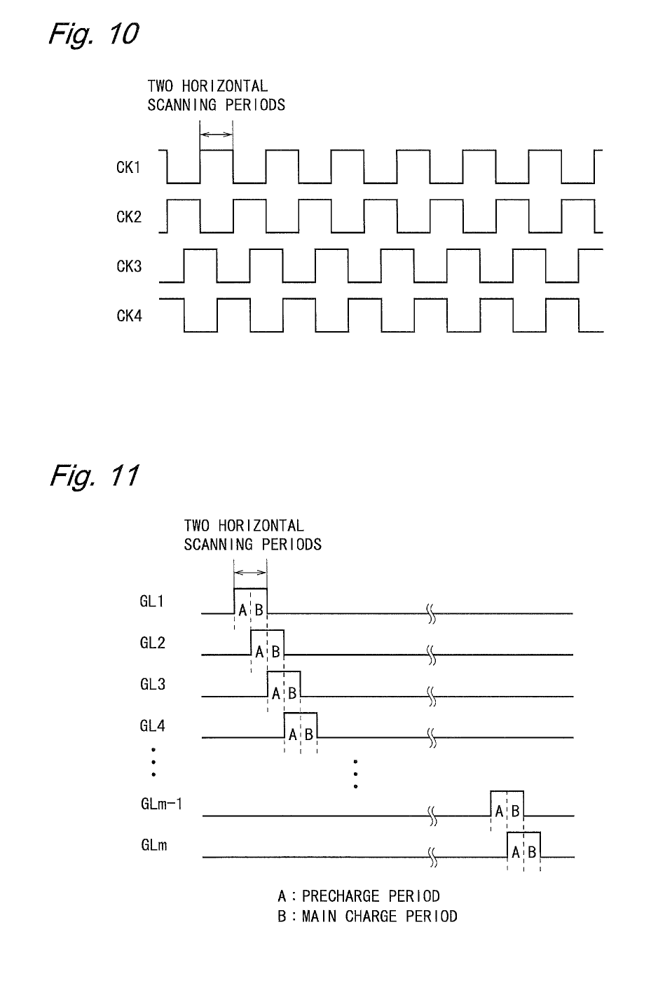

FIG. 10 is a timing chart of the clock signals CK1 to CK4. As shown in FIG. 10, each of the clock signals CK1 to CK4 becomes a high level every other two horizontal scanning periods. Relations between the phases of the clock signals CK1 to CK4 are the same as those in the first embodiment. The configuration of the unit circuit 11 is the same as that in the first embodiment (see FIG. 4). The timing chart of the unit circuit 11 is the same as that shown in FIG. 5 other than that one horizontal scanning period is changed to two horizontal scanning periods.

The clock signals of four phases shown in FIG. 10 are supplied to the two shift registers shown in FIG. 9, and the first gate start pulse signal GSP1, the second gate start pulse signal GSP2, the first gate end pulse signal GEP1, the second gate end pulse signal GSP2, the third gate end pulse signal N1EP1, and the fourth gate end pulse signal N1EP2 are controlled to be a high level for two horizontal scanning periods at predetermined timing. Accordingly, a pulse inputted to a first stage of the first shift register (first unit circuit UC (1)) is sequentially transferred to a last stage ((m−1)-th unit circuit UC (m−1)), and a pulse inputted to a first stage of the second shift register (second unit circuit UC (2)) is sequentially transferred to a last stage (m-th unit circuit UC (m)). At this time, the potentials of the scanning signal lines GL1 to GLm are changed to a high level sequentially for two horizontal scanning periods delaying by one horizontal scanning period (see FIG. 11).

Also in the shift register according to this embodiment, similarly to the first embodiment, the gate terminal of the TFT T8 is connected to the gate terminal of the TFT T2 included in the next stage unit circuit 11. Therefore, according to the shift register of this embodiment, by applying the post-boot potential Vb outputted from the next stage unit circuit 11 to the gate terminal of the TFT T8, it is possible to improve the driving capability of the TFT T8 and to decrease the falling time duration of the output signal Q or to reduce the layout area of the TFT T8.

Further, in the shift register according to this embodiment, the potentials of the scanning signal lines GL1 to GLm are at a high level during two horizontal scanning periods (see FIG. 11). The selection period of the i-th scanning signal line GLi is divided into two periods of a first half and a latter half. In the first half, the scanning signal line GLi and a previous scanning signal line GLi−1 are selected, and precharge (preliminary charge) to the scanning signal line GLi is performed. In the latter half, the scanning signal line GLi and a next scanning signal line GLi+1 are selected, and main charge (primary charge) to the scanning signal line GLi is performed.

In the shift register according to this embodiment, similarly to the first embodiment, not only the TFT T2 but also the TFT T8 is turned to the ON state when the output signal Q is rising. Accordingly, rising time duration for the output signal Q (time required before the signal becomes a high level) increases corresponding to an amount of the current flowing through the TFT T8. Thus, the shift register according to this embodiment starts an operation for setting the output signal Q outputted from the unit circuit UC (i) to a high level while the output signal Q outputted from the previous unit circuit UC (i−1) is at a high level. Accordingly, even when the rising time duration of the output signal Q is long, the output signal Q can be set to a high level within a predetermined time period (here, two horizontal scanning periods).

In the above example of values shown in the first embodiment, for example, when the TFTs T2 and T8 are both in the ON state, the current I2 flowing through the TFT T2 is I2=6.84×10⁻³ and the current I8 flowing through the TFT T8 is I8=1.98×10⁻³. Therefore, assuming that the rising time duration of the output signal Q at this time is T, and that the rising time duration of the output signal Q provided that the TFT T8 is in the OFF state when the TFT T2 is in the ON state is To, T=6.84/(6.64−1.98)×To=1.41 To is established.

By contrast, as described above, the potential of each scanning signal line GLi is changed to a high level for two horizontal scanning periods. Therefore, if the rising time duration of the output signal Q for the conventional shift register is within one horizontal scanning period, the rising time duration of the output signal Q becomes shorter than the selection period of the scanning signal lines GLi, even if the rising time duration of the output signal Q increases by 1.41 times as a result of an application of the present invention. Therefore, it is possible to correctly charge the scanning signal lines GLi within a predetermined selection period.

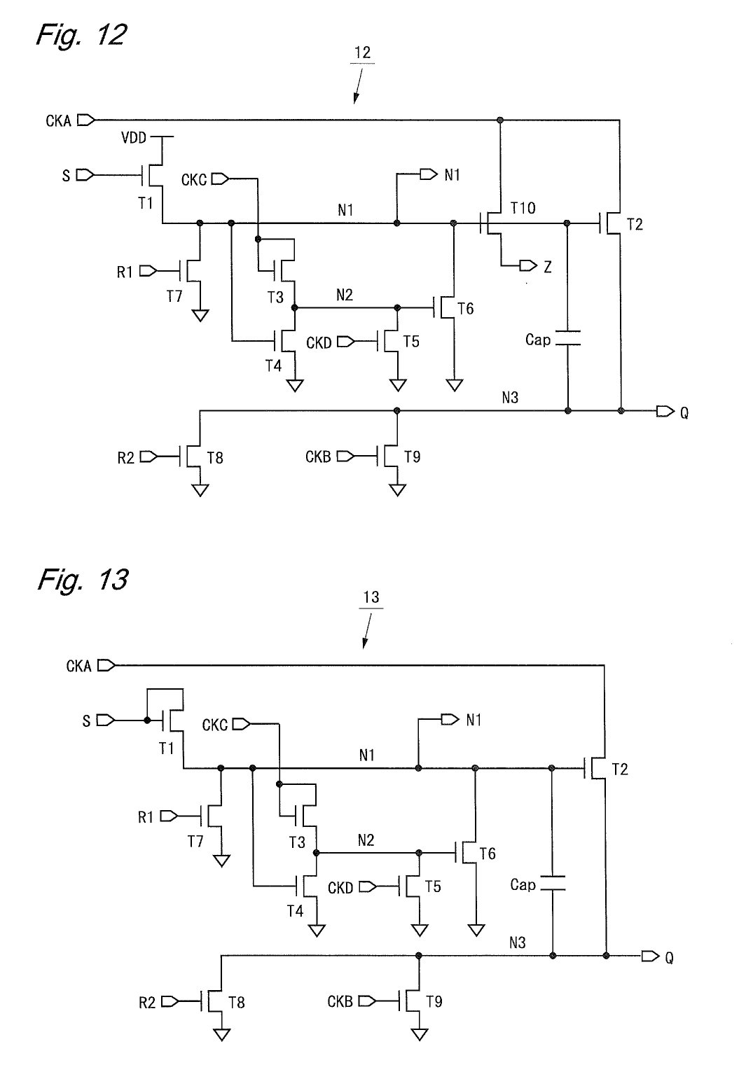

It should be noted that the shift register according to the embodiments of the present invention can be configured as modified examples described below. For example, in place of the unit circuit 11 shown in FIG. 4, any of unit circuits 12 to 15 respectively shown in FIG. 12 to FIG. 15 can be cascade-connected. In the shift register according to these modified examples, similarly, the gate terminal of the TFT T8 is connected to the gate terminal of the TFT T2 included in a next stage unit circuit.

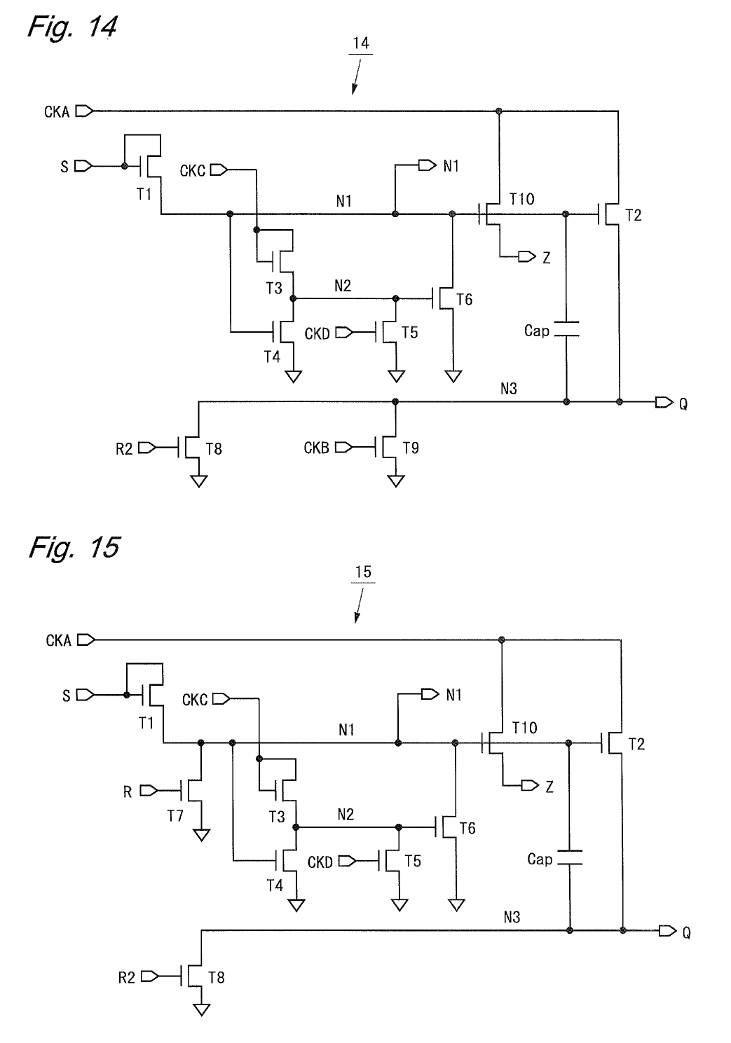

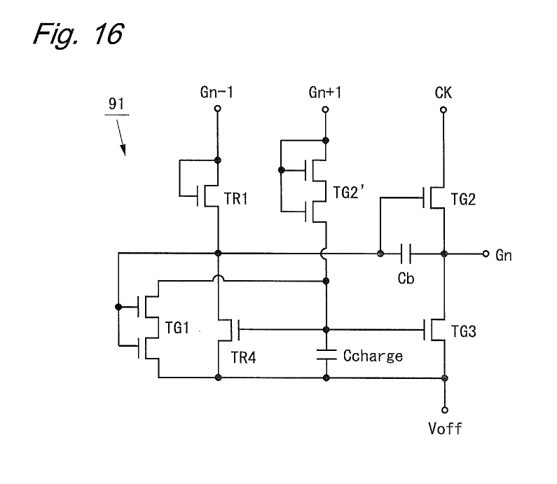

For the unit circuit 12 (FIG. 12), the set signal S is supplied to the gate terminal of the TFT T1 (the control terminal of the input transistor), and a high level potential VDD is fixedly applied to the drain terminal of the TFT T1 (the other control terminal of the input transistor). According to this circuit configuration, the ON potential can be applied to the gate terminal of the TFT T2 using the TFT T1. The unit circuit 13 (FIG. 13) does not include the TFT T10 (additional output transistor). When cascade-connecting the unit circuits 13, the gate terminal of the TFT T1 (the control terminal of the input transistor) is connected to the output node N3 included in a previous stage unit circuit 13. Accordingly, the TFT T1 can be controlled with a simple circuit configuration. The unit circuit 14 (FIG. 14) does not include the TFT T7 (state reset transistor). The unit circuit 15 (FIG. 15) does not include the TFT T9 (output reset auxiliary transistor). Using the unit circuits 14 or 15 allows reduction of an amount of circuits.

Further, all of the transistors included in the unit circuits can be of a P-channel type. Alternatively, each unit circuit can be configured by P-channel type transistors and N-channel type transistors. Further, the present invention can also be applied to a shift register included in a display device other than the liquid crystal display device, an imaging device, or the like.

### INDUSTRIAL APPLICABILITY

The shift register according to the present invention is able to reset the output signal at high speed and has a small area, and therefore can be applied to a drive circuit and the like in a display device or in an imaging device.

### DESCRIPTION OF REFERENCE CHARACTERS

1: Power Supply

2: DC/DC Converter

3: Display Control Circuit

4: Scanning Signal Line Drive Circuit

5: Video Signal Line Drive Circuit

6: Common Electrode Drive Circuit

7: Pixel Region

8: Liquid Crystal Panel

11 to 15: Unit Circuit

1. A shift register configured such that a plurality of unit circuits are cascade-connected and operating based on a plurality of clock signals, wherein
each unit circuit includes:
an output transistor having one conducting terminal supplied with one of the clock signals and the other conducting terminal connected to an output node;
an input transistor configured to apply an ON potential to a control terminal of the output transistor according to a supplied set signal; and
an output reset transistor configured to apply an OFF potential to the output node according to a supplied output reset signal, and
a control terminal of the output reset transistor is connected to a control terminal of an output transistor included in a next stage unit circuit.

2. The shift register according to claim 1, wherein
each unit circuit further includes a state reset transistor configured to apply an OFF potential to the control terminal of the output transistor according to a supplied state reset signal.

3. The shift register according to claim 1, wherein
each unit circuit further includes an output reset auxiliary transistor configured to apply an OFF potential to the output node according to another one of the supplied clock signals.

4. The shift register according to claim 1, wherein
the set signal is supplied to a control terminal and one conducting terminal of the input transistor.

5. The shift register according to claim 1, wherein
the set signal is supplied to a control terminal of the input transistor, and the ON potential is fixedly applied to one conducting terminal of the input transistor.

6. The shift register according to claim 1, wherein
each unit circuit further includes an additional output transistor having a control terminal and one conducting terminal connected in an identical configuration with that of the output transistor, and
a control terminal of the input transistor is connected to the other conducting terminal of an additional output transistor included in a previous stage unit circuit.

7. The shift register according to claim 1, wherein
a control terminal of the input transistor is connected to an output node included in a previous stage unit circuit.

8. The shift register according to claim 1, wherein
all of the transistors included in the unit circuits are of the same conductivity type.

9. A display device comprising:
a plurality of pixel circuits arranged two-dimensionally; and
a drive circuit including the shift register according to claims 1.

10. A display device comprising:
a plurality of pixel circuits arranged two-dimensionally; and
a drive circuit including the shift register according to claim 2.

11. A display device comprising:
a plurality of pixel circuits arranged two-dimensionally; and
a drive circuit including the shift register according to claim 3.

12. A display device comprising:
a plurality of pixel circuits arranged two-dimensionally; and
a drive circuit including the shift register according to claim 4.

13. A display device comprising:
a plurality of pixel circuits arranged two-dimensionally; and
a drive circuit including the shift register according to claim 5.

14. A display device comprising:
a plurality of pixel circuits arranged two-dimensionally; and
a drive circuit including the shift register according to claim 6.

15. A display device comprising:
a plurality of pixel circuits arranged two-dimensionally; and
a drive circuit including the shift register according to claim 7.

16. A display device comprising:
a plurality of pixel circuits arranged two-dimensionally; and
a drive circuit including the shift register according to claim 8.
